(19) United States
(12) Patent Application Publication
(10) Pub. No.: US 2003/0183934 A1
(43) Pub. Date: Oct. 2, 2003

(54) Method and apparatus for stacking multiple die in a flip chip semiconductor package

(76) Inventor: Joseph C. Barrett, El Dorado, CA (US)

Correspondence Address: Calvin Wells, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/112,631

(22) Filed: Mar. 29, 2002

(51) Int. Cl. H01L 21/44; H01L 21/48; H01L 21/50; H01L 23/48; H01L 23/52; H01L 29/40

(52) U.S. Cl. 257/738; 438/108

(57) ABSTRACT

A semiconductor package is disclosed where the package includes a first die mounted to first surface of a second die. The first surface of the second die is then mounted to a substrate. The substrate includes a hole of appropriate size to receive the first die and to allow the second die to be mounted to the substrate using conventional interconnection and assembly techniques.

### FIELD OF THE INVENTION

The present invention pertains to the field of semiconductor devices. More particularly, this invention pertains to the field of semiconductor device packaging.

### BACKGROUND OF THE INVENTION

One common type of semiconductor device packaging is known as “flip chip” packaging. Prior flip chip packaging consists of a single die mounted to a package substrate. An example of such a prior flip chip package is shown in FIG. 1. The package of FIG. 1 includes a die 110 mounted to a substrate 130. The die 110 is electrically connected to the substrate 130 by way of conductive balls or bumps on the bottom side of die 110. The under fill epoxy 120 is used to provide strain relief and to reinforce the mechanical connection between the die 110 and the substrate 130. The package of FIG. 1 also includes solder balls 140 which will provide electrical connections to a circuit board when the package of FIG. 1 is mounted to the circuit board.

With prior flip chip packages, if a product requires more than one die within the package, as may be desirable in order to provide additional features or configurability, the additional die are bonded to the substrate along side the original die. An example of this is shown in FIG. 2. The package of FIG. 2 includes a die 210 and an additional die 215. The die 210 and the die 215 are each mounted to the substrate 230. Under fill epoxy 220 is used to strengthen the mechanical bond between the die 210 and the substrate 230 and also between the die 215 and the substrate 230. Solder balls 240 will provide electrical connections to a circuit board when the package of FIG. 2 is mounted to the circuit board. Including multiple die on a substrate in side-by-side fashion as depicted in FIG. 2 typically results in a larger, more complex substrate and therefore increased package cost.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a block diagram of a prior flip chip package.

FIG. 2 is a block diagram of a prior flip chip package with more than one die.

FIG. 3 is a block diagram of one embodiment of a package with one die mounted to a surface of another die which is then mounted to a substrate.

FIG. 4 is a block diagram of one embodiment of a package with more than one die mounted to a surface of an additional die which is then mounted to a substrate.

FIG. 5 is a block diagram of one embodiment of a system including a chipset component having more than one die.

### DETAILED DESCRIPTION

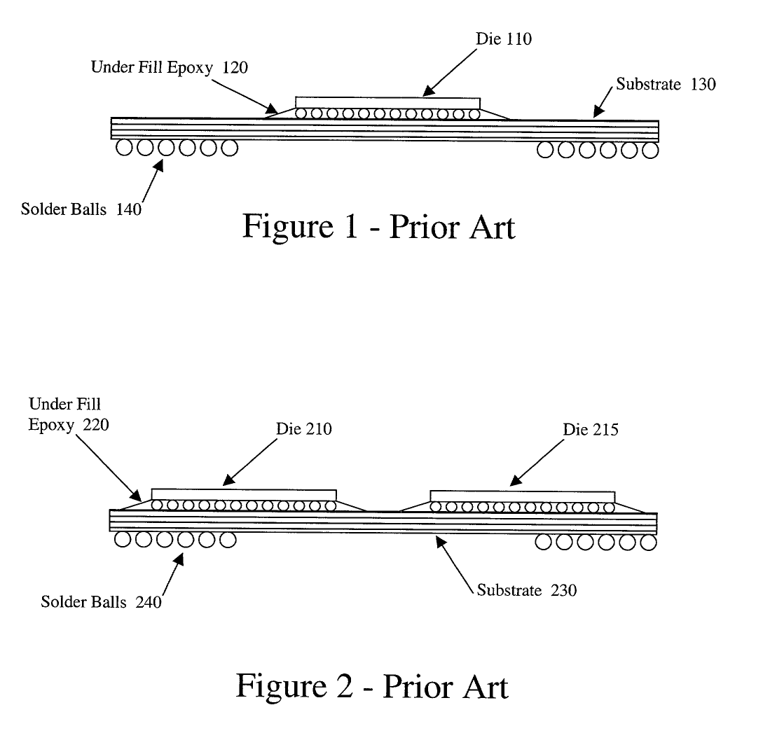

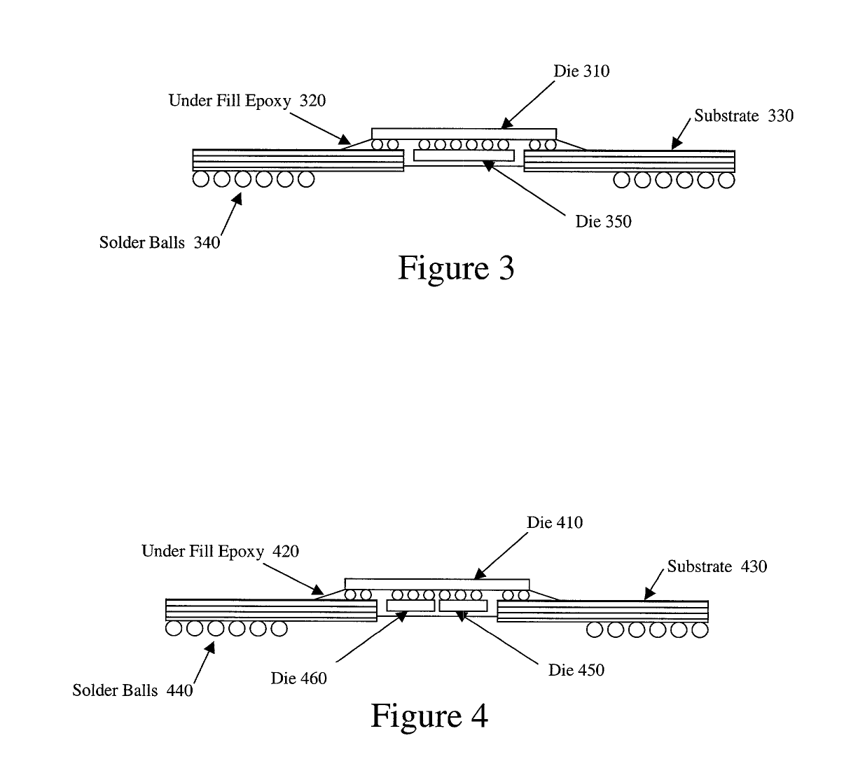

FIG. 3 is a block diagram of one embodiment of a package with a die 350 mounted to a surface of another die 310 which is then mounted to a substrate 330. This differs from prior flip chip packages such as that shown in FIG. 2 in that one die is mounted to another die rather than mounting each die adjacent to each other on the substrate. The configuration of FIG. 3 results in a reduction of package size and cost when more than one die is needed.

For the example embodiment of FIG. 3, the die 350 is mounted to the die 310 by way of a ball grid array. The die 310 is mounted to the substrate 330 also by way of a ball grid array. Although the use of ball grid arrays are discussed in connection with FIG. 3, other embodiments are possible using pin grid arrays, land grid arrays, or bump grid arrays for the connections between the die 350 and the die 310 and also for the connections between the die 310 and the substrate 330.

The substrate 330 features a hole of appropriate size to receive the die 350 and to allow the die 310 to be mounted to the substrate using conventional flip chip interconnection and assembly techniques. Although the hole in the substrate 330 is shown to extend from the top surface of the substrate 330 all the way to the bottom surface of the substrate 330, other embodiments are possible using holes that do not extend all the way to the bottom surface.

Under fill epoxy 320 may be used under the die 310 and surrounding the die 350 in order to provide strain relief and to ensure satisfactory reliability of the assembled package.

In assembling the package of FIG. 3, the die 350 would first be mounted to the die 310, then the die 310 would be mounted to the substrate 330. The under fill epoxy 320 may then be applied.

The substrate 330 may be implemented using organic materials or may be implemented using other substrate technologies, such as ceramic.

FIG. 4 is a block diagram of one embodiment of a package with a die 450 and an additional die 460 mounted to a surface of another die 410 which is then mounted to a substrate 430.

For the example embodiment of FIG. 4, the die 450 and the die 460 are mounted to the die 410 by way of a ball grid array. The die 410 is mounted to the substrate 430 also by way of a ball grid array. Although the use ball grid arrays are discussed in connection with FIG. 4, other embodiments are possible using pin grid arrays, land grid arrays, or bump grid arrays for the connections between the die 450 and the die 410, between the die 460 and the die 410, and further for the connections between the die 410 and the substrate 430.

The substrate 430 features a hole of appropriate size to receive the die 450 and the die 460 and to allow the die 410 to be mounted to the substrate 430 using conventional flip chip interconnection and assembly techniques. Although the hole in the substrate 430 is shown to extend from the top surface of the substrate 430 all the way to the bottom surface of the substrate 430, other embodiments are possible using holes that do not extend all the way to the bottom surface.

As with the example embodiment discussed above in connection with FIG. 3, under fill epoxy 420 may be used under the die 410 and surrounding the die 450 and the die 460 in order to provide strain relief and to ensure satisfactory reliability of the assembled package.

In assembling the package of FIG. 4, the die 450 and the die 460 would first be mounted to the die 410, then the die 410 would be mounted to the substrate 430. The under fill epoxy 420 may then be applied.

As with the example embodiment of FIG. 3, the substrate 430 may be implemented using organic materials or may be implemented using other substrate technologies, such as ceramic.

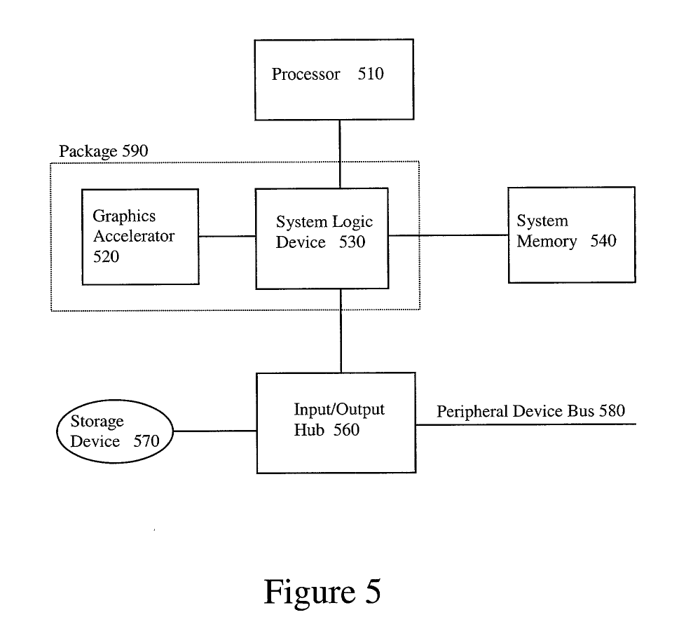

FIG. 5 is a block diagram of one embodiment of a system including a chipset component enclosed in a package 590 having more than one die. For this example embodiment, the package 590 includes a first die implementing a graphics accelerator 520 and a second die implementing a system logic device 530.

The package 590 is coupled to a processor 510, a system memory 540, and an input/output hub 560. The input/output hub is further coupled to a peripheral device bus 580 and a storage device 570.

The package 590 may be implemented in accordance with the example embodiment described above in connection with FIG. 3. The graphics accelerator 520 corresponds to the die 350 of FIG. 3 and the system logic device 530 corresponds to the die 310 of FIG. 3.

Although the example embodiment of FIG. 5 includes a graphics accelerator and a system logic device sharing a package in accordance with the example embodiment described in connection with FIG. 3, other embodiments are possible with any of a wide range of devices being combined. For example, a die including a cache memory may be coupled with a die including a system logic (chipset) device having a cache controller. Another example may include a die including a graphics memory coupled with a die including a graphics controller.

In addition to the techniques described above, other embodiments are possible where one die is wire-bonded to another die. Further, although the above example embodiments are discussed in connection with system logic devices within a computer system, other embodiments are possible for other devices used in cell phones, pagers, and anywhere else that semiconductor devices are used.

In the foregoing specification the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than in a restrictive sense.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances of “an embodiment,” “one embodiment,” or “some embodiments” are not necessarily all referring to the same embodiments.

What is claimed is:

1. An apparatus, comprising:
a substrate including a first surface and a second surface, the substrate further including a hole extending at least partially from the first surface to the second surface;
a first die including a first surface and a second surface, the first surface of the first die mounted to the first surface of the substrate; and
a second die mounted to the first surface of the first die.

2. The apparatus of claim 1, wherein the second die is mounted to the first die using a ball grid array.

3. The apparatus of claim 1, wherein the first die is mounted to the substrate using a ball grid array.

4. The apparatus of claim 1, wherein the second die is mounted to the first die using a land grid array.

5. The apparatus of claim 1, wherein the first die is mounted to the substrate using a land grid array.

6. The apparatus of claim 1, wherein the second die is mounted to the first die using a pin grid array.

7. The apparatus of claim 1, wherein the first die is mounted to the substrate using a pin grid array.

8. The apparatus of claim 1, wherein the second die is mounted to the first die using a bump grid array.

9. The apparatus of claim 1, wherein the first die is mounted to the substrate using a bump grid array.

10. The apparatus of claim 1, wherein the first die includes a chipset device, the chipset device including a cache controller.

11. The apparatus of claim 10, wherein the second die includes a cache memory.

12. The apparatus of claim 1, wherein the first die includes a chipset device, the chipset device including an interface to a graphics device.

13. The apparatus of claim 12, wherein the second die includes a graphics device.

14. The apparatus of claim 1, wherein the first die includes a chipset device, the chipset device including a graphics controller.

15. The apparatus of claim 14, wherein the second die includes a graphics memory.

16. A method, comprising:
mounting a second die to a first surface of a first die; and
mounting the first surface of the first die to a substrate, the substrate including a hole to accommodate the second die.

17. The method of claim 16, wherein mounting the second die to the first surface of the first die includes mounting the second die to the first surface of the first die using a ball grid array.

18. The method of claim 16, wherein mounting the second die to the first surface of the first die includes mounting the second die to the first surface of the first die using a land grid array.

19. The method of claim 16, wherein mounting the second die to the first surface of the first die includes mounting the second die to the first surface of the first die using a pin grid array.

20. The method of claim 16, wherein mounting the first surface of the first die to the substrate includes mounting the first surface of the first die to the substrate using a ball grid array.

21. The method of claim 16, wherein mounting the first surface of the first die to the substrate includes mounting the first surface of the first die to the substrate using a land grid array.

22. The method of claim 16, wherein mounting the first surface of the first die to the substrate includes mounting the first surface of the first die to the substrate using a pin grid array.

23. The method of claim 16, wherein mounting the first surface of the first die to the substrate includes mounting the first surface of the first die to the substrate using a bump grid array.

24. The method of claim 16, wherein mounting the first surface of the first die to the substrate includes mounting the first surface of the first die to the substrate using a bump grid array.

25. A system, comprising:
a processor; and
a chipset component coupled to the processor, the component including a first device implemented on a first die and a second device implemented on a second die, the chipset component including
a substrate having a first surface and a second surface, the substrate further including a hole extending at least partially from the first surface to the second surface, the first die including a first surface and a second surface, the first surface of the first die mounted to the first surface of the substrate, and the second die mounted to the first surface of the first die.

26. The system of claim 25, wherein the second die is mounted to the first die using a ball grid array.

27. The system of claim 25, wherein the first die is mounted to the substrate using a ball grid array.

28. The system of claim 25, wherein the second die is mounted to the first die using a land grid array.

29. The system of claim 25, wherein the first die is mounted to the substrate using a land grid array.

30. The system of claim 25, wherein the first die includes a system logic device, the system logic device including a cache controller.

31. The system of claim 30, wherein the second die includes a cache memory.

32. The system of claim 25, wherein the first die includes a system logic device, the system logic device including an interface to a graphics device.

33. The system of claim 32, wherein the second die includes a graphics device.
